(19) United States
(12) Patent Application Publication
(10) Pub. No.: US 2012/0223299 A1
(43) Pub. Date: Sep. 6, 2012

(54) METAL/OXIDE ONE TIME PROGAMMABLE MEMORY

(76) Inventor: Jun Liu, Boise, ID (US)

(21) Appl. No.: 13/040,523

(22) Filed: Mar. 4, 2011

(51) Int. Cl. H01L 29/12; H01L 21/8246

(52) U.S. Cl. 257/43; 438/104; 257/E29.068; 257/E21.662

(57) ABSTRACT

Embodiments include memory cells having an oxide material in contact with a metal material. In one embodiment, a memory cell includes titanium nitride, titanium oxynitride in contact with the titanium nitride and copper in contact with the titanium oxynitride. A plurality of such memory cells and respective access devices can be included in a memory array. The memory cell and access device are electrically connected between an access line and a data/sense line. An array can include a plurality of memory cells vertically stacked with respective access devices. Embodiments also include methods of forming memory cells and arrays and stacking memory arrays over one another.

### FIELD OF THE INVENTION

Embodiments of the invention relate to semiconductor devices and, in particular, to one time programmable (OTP) memory cells and devices and methods of forming the same.

### BACKGROUND OF THE INVENTION

There continues to be a need for semiconductor memory with increased density. One solution to increase density has been a vertically stacked non-volatile memory device, which includes memory cells having a PN junction diode with a poly-oxide-poly dielectric rupture antifuse device. (See, for example, U.S. Pat. No. 6,034,882). Such a memory device, however, has drawbacks, including slow programming speed, high voltage operation, high on state resistance and poor long term reliability due to on state self-annealing of the oxide breakdown path.

With increased density it remains important to minimize power consumption and have a device with good long term reliability. Accordingly, it would be desirable to have an improved high density OTP memory device.

### BRIEF DESCRIPTION OF THE DRAWINGS

FIGS. 1A-1B are cross-sectional views of memory arrays according to embodiments of the invention.

FIG. 2 is an electrical diagram of the memory array of FIG. 1A.

FIG. 3 is cross-sectional view of a memory cell according to an embodiment.

FIGS. 4A-4C illustrate a programming operation of a memory cell according to an embodiment of the invention.

FIG. 4D is a graph of the voltage versus the current for an experimental programming operation on a memory cell having a TiN/TiOₓN_{y}/Cu structure.

FIGS. 5A-5E depict the formation of the memory array of FIG. 1A according to an embodiment of the invention.

FIGS. 6A-6C depict the formation of a memory cell according to an embodiment of the invention.

FIGS. 7A-7C are cross-sectional views of a memory array according to embodiments of the invention.

FIG. 8 is a block diagram of a processor system incorporating a memory array and/or memory cell in accordance with an embodiment of the invention.

### DETAILED DESCRIPTION OF THE INVENTION

In the following detailed description, reference is made to various embodiments of the invention. These embodiments are described with sufficient detail to enable those skilled in the art to practice them. It is to be understood that other embodiments may be employed, and that various structural, logical and electrical changes may be made.

The term “substrate” used in the following description may include any supporting structure including, but not limited to, a semiconductor substrate that has an exposed substrate surface. A semiconductor substrate should be understood to include silicon, silicon-on-insulator (SOI), silicon-on-sapphire (SOS), doped and undoped semiconductors, epitaxial layers of silicon supported by a base semiconductor foundation, and other semiconductor structures, including those made of semiconductors other than silicon. When reference is made to a semiconductor substrate or wafer in the following description, previous process steps may have been utilized to form regions or junctions in or over the base semiconductor or foundation. The substrate also need not be semiconductor-based, but may be any support structure suitable for supporting an integrated circuit, including, but not limited to, metals, alloys, glasses, polymers, ceramics, and any other supportive materials as is known in the art.

Embodiments of the invention include memory cells having an oxide in contact with a metal that, upon the application of an electric field sufficient to program the memory cell into a low resistance state, the oxide is weakened such that the metal moves into the oxide to create a conductive pathway. Since the oxide is weakened upon programming, the conductive pathway is not easily broken such that the memory cell behaves as a one time programmable (OTP) memory cell. Unlike other memory cells that operate based on the movement of metal ions in and out of a material, such as conduction bridge RAM, memory cells according to the embodiments described herein may not rely on an oxidation reduction (redox) mechanism to facilitate movement of the metal into the oxide and the conduction pathway formed within memory cells according to the embodiments described herein is more permanent.

In one embodiment, the memory cells include titanium nitride (TiN), titanium oxynitride (TiOₓN_{y}) in contact with the titanium nitride, and copper (Cu) in contact with the titanium oxynitride. In another embodiment, the memory cells include any one of zirconium oxide (ZrO₂), aluminum oxide (Al₂O₃) and tantalum oxide (Ta₂O₅) in contact with a metal, such as copper. A plurality of such memory cells can be included in a memory array. Each memory cell is electrically connected to an access device (such as a transistor, diode, PN junction diode, or other suitable access device). Each memory cell and respective access device are electrically connected between an access line and a data/sense line, for example a word line and a bitline, respectively. In one embodiment the memory cell is an OTP memory cell. In one embodiment, an array includes a plurality of memory cells vertically stacked with respect to respective access devices. In another embodiment, multiple levels of arrays are vertically stacked over one another, each array level including a plurality of memory cells vertically stacked with respect to respective access devices. Embodiments of the invention also include methods of forming such memory cells and arrays, which are described herein in more detail.

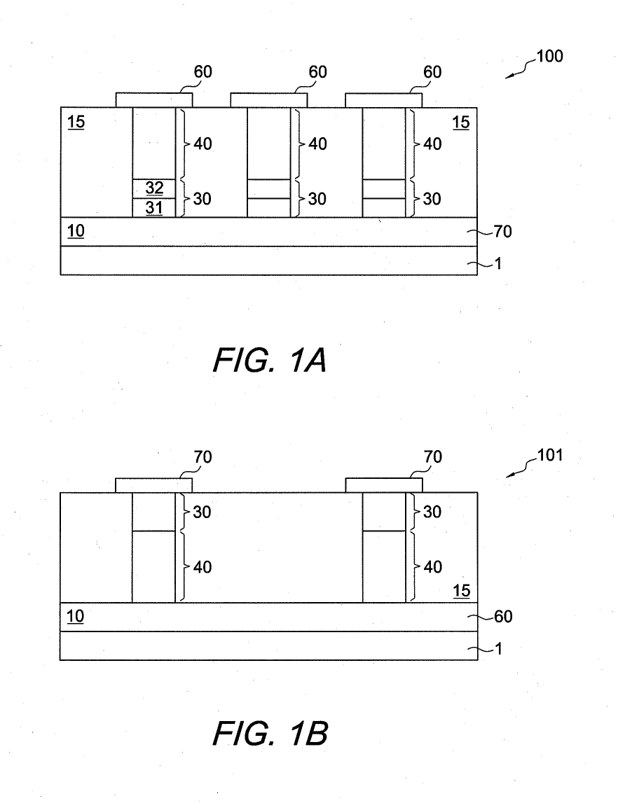

FIGS. 1A-1B are cross-sectional views of memory arrays according to embodiments of the invention.

Referring to FIG. 1A, the array 100 is supported by a substrate 1. In the illustrated embodiment, the substrate 1 is a dielectric material, which can be located over other devices and materials on a memory device.

A metal material 10 overlies the substrate 1. In the illustrated embodiment, the metal material 10 serves as a data/sense line 70. In the illustrated embodiment, the metal material 10 is tungsten, but any suitable conductive material may be used. In one embodiment, the thickness of the metal material 10 is from about 20 nm to about 1000 nm.

A plurality of access devices 30 are electrically connected to the metal material 10. In the present embodiment the access devices 30 are PN junction diodes having a heavily doped n-type (n+) silicon material 31 below and in contact with a heavily doped p-type (p+) silicon material 32. In one embodiment, the thicknesses of each of the n-type silicon material 31 and p-type silicon material 32 are from about 20 nm to about 100 nm.

Rather than a PN junction diode as shown in FIG. 1A, the access device could be another suitable device that provides access to the memory cell 40, such as a transistor or other type of diode.

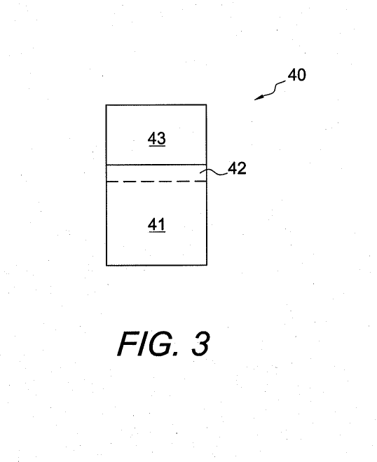

A memory cell 40 is in electrical contact with each access device 30. The memory cells 40 can be those depicted in and described in more detail in connection with FIG. 3. Although FIG. 1A shows only three memory cells 40 and three access devices 30, it should be readily understood that the array 100 can include any number of memory cells 40 and access devices 30.

According to the embodiment of FIG. 1A, the memory cell 40 is in contact with the p+ silicon material 32, such that the memory cell 40 is vertically stacked over the access device 30. The memory cells 40 are electrically connected to an access line 60.

The access devices 30 and memory cells 40 are vertically stacked within a dielectric material 15. Alternatively, one or both of the memory cell 40 and access device 30 could be horizontally oriented. Dielectric material 15 can include one or more different dielectric materials. In one embodiment, the dielectric material 15 is a material that prevents the diffusion of copper material 43. In one embodiment, at least a portion or all of the dielectric material is silicon nitride (SiN). In one embodiment, at least a portion or all of the dielectric material is silicon dioxide (SiO₂).

FIG. 1B depicts an alternative embodiment of an array 101 including memory cells 40. In the FIG. 1B embodiment, the access devices 30 are stacked over the memory cells 40.

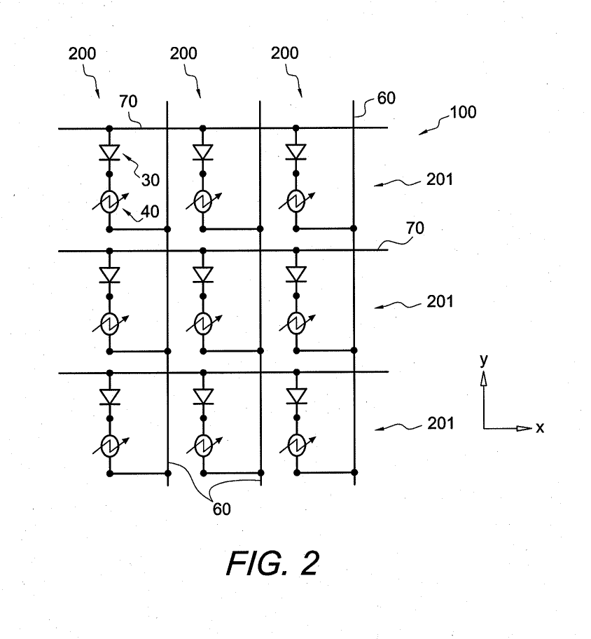

FIG. 2 is an electrical diagram of the memory array 100 of FIG. 1A. As illustrated in FIG. 2, each memory cell 40 is electrically connected between an access device 30, which is shown as a diode, and an access line 60. Each access device 30 is electrically connected between the memory cell 40 and a data/sense line 70. The memory cells 40 and access devices 30 are arranged in columns 200 along the y direction and rows 201 along the x direction. Within each row 201, the access devices 30 are connected to a common data/sense line 70. Within each column 200, the memory cells 40 are connected to a common access line 60.

FIG. 3 depicts a memory cell 40 in more detail. As shown in FIG. 3, the memory cell 40 includes a conductive material 41 in contact with an oxide material 42, which in turn, is in contact with a metal material 43. In one embodiment, the conductive material 41 is TiN, the oxide material 42 is TiOₓN_{y} and the metal material 43, is copper. In one embodiment, the thickness of the conductive material 41 is from about 3 nm to about 80 nm. In one embodiment, the thickness of the oxide material 42 is from about 2 nm to about 10 nm. In one embodiment, the thickness of the metal material 43 is from about 10 nm to about 100 nm.

Alternatively, the material 42 can be an oxide material, selected from the group consisting of TiOₓN_{y}, ZrO₂, Al₂O₃ and Ta₂O₅. Also as an alternative, the conductive material 41 can be a material, which when oxidized, will form one of TiOₓN_{y}, ZrO₂, Al₂O₃ and Ta₂O₅.

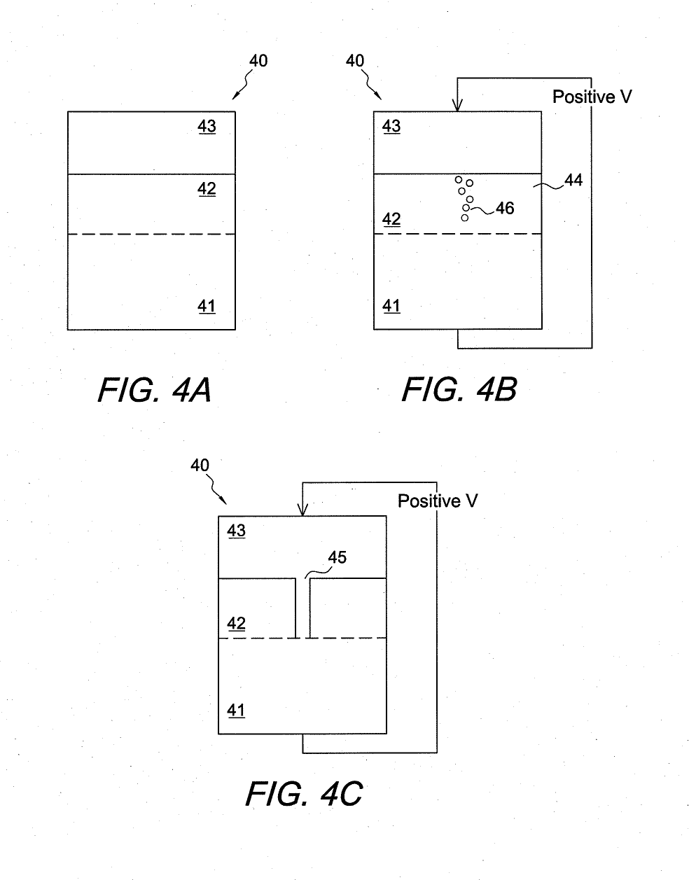

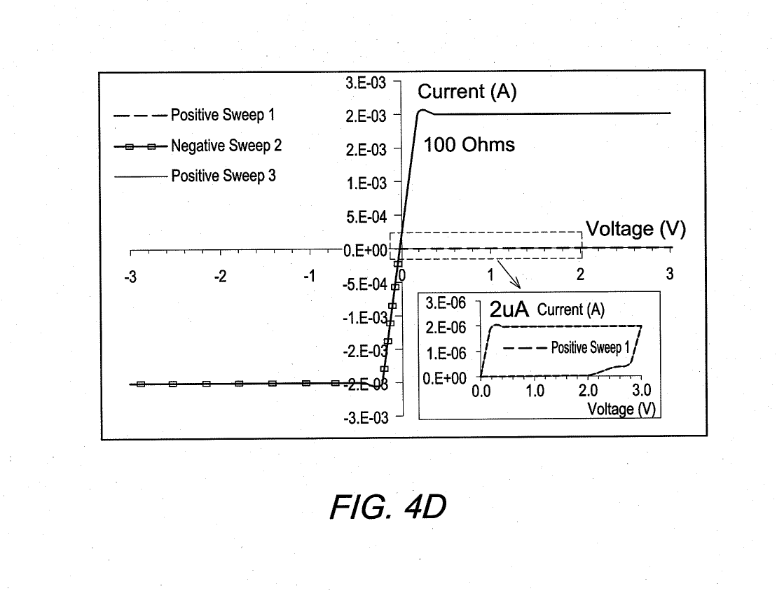

FIGS. 4A-4C illustrate a programming operation of a memory cell 40 according to an embodiment of the invention. FIG. 4A depicts an un-programmed memory cell 40 having a TiN material 41 in contact with a TiOₓN_{y} material 42, which, in turn, is in contact with a Cu material 43 (a “TiN/TiOₓN_{y}/Cu structure”). To program the memory cell 40, a positive voltage is applied across memory cell 40, as shown in FIG. 4B. Upon application of the voltage, the applied electric field breaks down the TiOₓN_{y} material 42 to form a path 46 that Cu ions 44 move through. FIG. 4C shows the programmed memory cell 40 in which the Cu ions 44 (FIG. 4B) have formed a Cu filament 45. The Cu filament 45 enables a low Ohmic resistance in the “on” or programmed state of the memory cell 40. In addition, because there is a Cu filament 45, self-annealing of the oxide breakdown path does not occur to impair the reliability of the memory cell 40.

FIG. 4D is a graph of the voltage versus the current for an experimental programming operation on a memory cell having a TiN/TiOₓN_{y}/Cu structure. FIG. 4D shows memory cells with a programming voltage of less than about 3V and a programming current of about 2 μA. In addition, the on state (i.e., the memory cell is programmed to have a low resistance) can carry a current of up to about 1 mA and the on state resistance is less than about 100 Ohms.

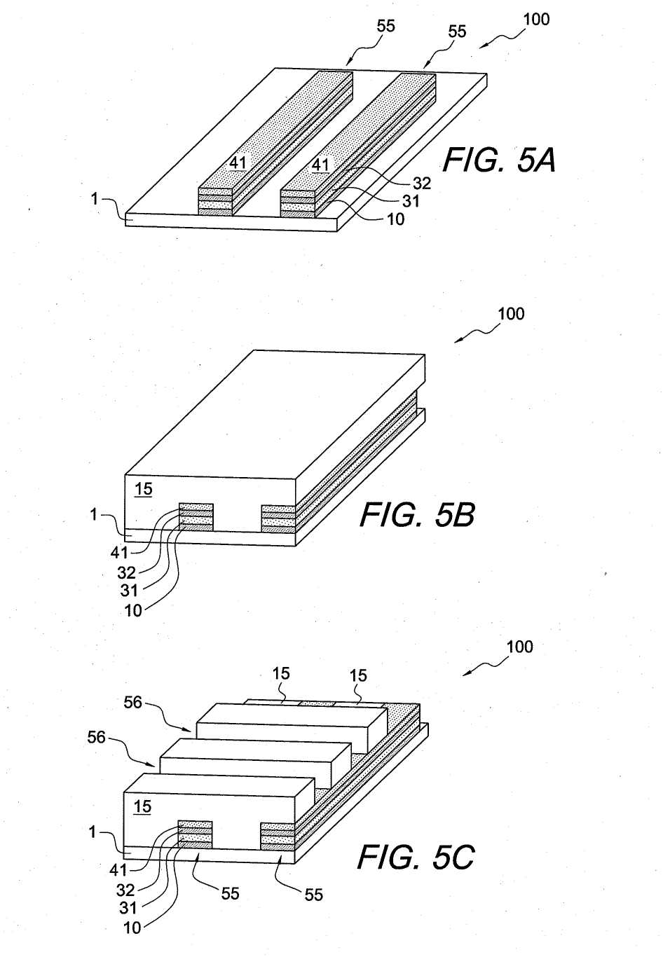

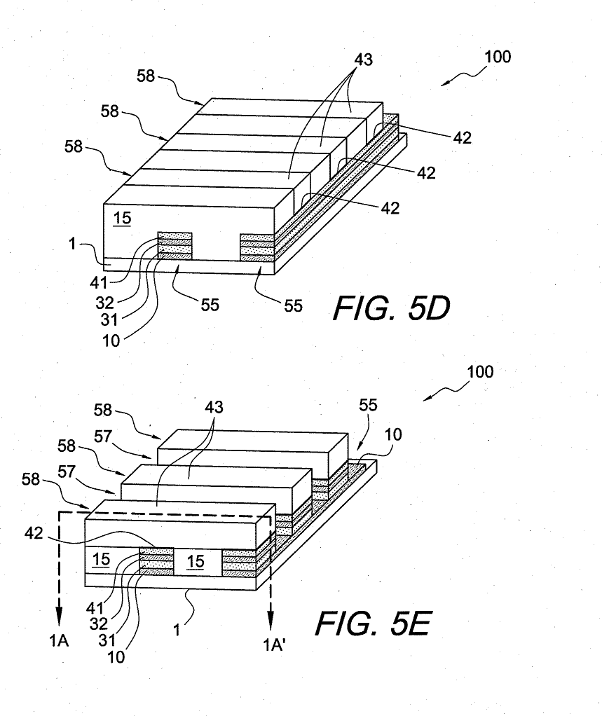

FIGS. 5A-5E depict the formation of the memory array 100 of FIG. 1A according to an embodiment of the invention. Although FIGS. 5A-5E depict the formation of only a limited number of memory cells 40 and access devices 41, additional memory cells 40 and access devices 30 can be formed simultaneously as part of the same processing steps. As described in more detail below, the method described in connection with FIGS. 5A-5E enables the memory cells 40 and access devices 30 and components thereof to be self-aligned, facilitating a very high density of memory cells 40 in the array 100.

Referring to FIG. 5A, a stack of blanket layers is formed over the substrate 1. The stack can include the metal material 10, n+ silicon material 31, p+ silicon material 32, and a conductive material 41 formed on the substrate 1. In one embodiment, the conductive material 41 can be any of TiN or any conductive material that when oxidized would result in the formation of any of TiOₓN_{y}, ZrO₂, Al₂O₃ and Ta₂O₅.

Each of the blanket layers 10, 31, 32, 41 can be formed by known techniques. For example, the n+ silicon material 31, p+ silicon material 32 can be formed by forming silicon and doping the silicon with p and n-type dopants. In one embodiment, the thicknesses of each of the n-type silicon material 31 and p-type silicon material 32 are from about 20 nm to about 100 nm. In one embodiment, the thickness of the metal material 10 is from about 20 nm to about 1000 nm. In one embodiment, the material 41 has a thickness from about 3 nm to about 80 nm. The blanket layers 10, 31, 32, 41, are processed by methods known in the art to form lines 55 of the stacked materials 10, 31, 32, 41 as shown in FIG. 5A.

FIG. 5B depicts the formation and planarization of a dielectric material 15. The dielectric material 15 is formed over and between the lines 55 by any suitable technique and then planarized. In one embodiment, the dielectric material 15 is a material that prevents the diffusion of the copper material 43 therein. In one embodiment, at least a portion or all of the dielectric material is SiN. In one embodiment, at least a portion or all of the dielectric material is SiO₂. In one embodiment, the thickness of the dielectric material 15 over the surface of the conductive material 41 after planarization is from about 10 nm to about 100 nm.

As shown in FIG. 5C, trenches 56 are formed by any suitable technique in the dielectric material 15 perpendicular to the lines 55. The trenches 56 are formed to expose the top surface of the conductive material 41.

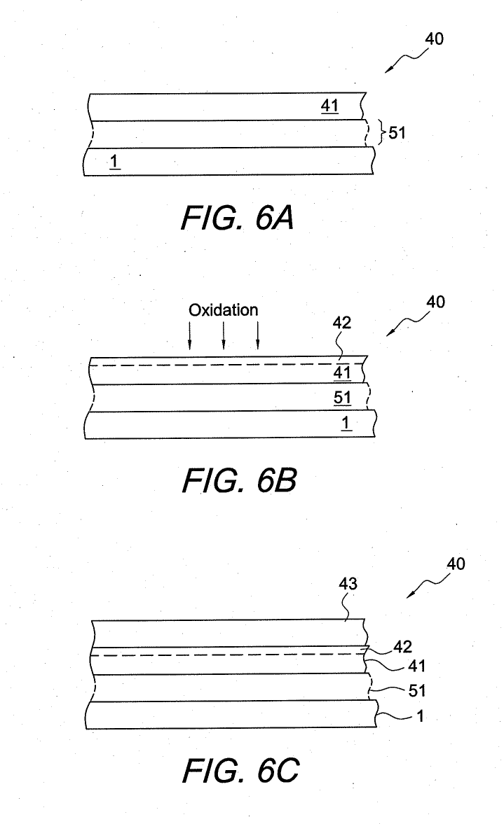

FIG. 5D shows the formation of the oxide material 42 on the exposed surfaces of material 41 and the metal material 43 within trenches 56. If the conductive material 41 is TiN or any conductive material that when oxidized would result in the formation of any of TiOₓN_{y}, ZrO₂, Al₂O₃ and Ta₂O₅, then prior to formation of the metal material 43 within trenches 56, the top surface of the conductive material 41 is oxidized. In one embodiment, where the conductive material 41 is TiN, the surface of the TiN is treated with O₂, N₂ and H₂ plasmas to oxidize the surface of the TiN material to form TiOₓN_{y} as the oxide material 42 (See, e.g., FIGS. 6A-6C). Alternatively, the oxide material 42 can be deposited on the surface of the conductive material 41.

In one embodiment, the thickness of the oxide material 42 is from about 2 nm to about 10 nm. The metal material 43 is then formed in the trenches 56 and in contact with the oxide material 42 and dielectric material 15 to form metal material lines 58. The metal material 43 can be formed and planarized by any suitable technique, such as a damascene process. In one embodiment, the metal material 43 is copper. In one embodiment the metal material 43 has a thickness of from about 10 nm to about 100 nm after planarization.

As shown in FIG. 5E, trenches 57 are fanned by any suitable technique perpendicular to the lines 55 and parallel to the metal material 43 lines 58. Trenches 57 isolate individual memory cells 40 (FIG. 1A) by removing portions of the dielectric material 15, conductive material 41, oxide material 42, n-type silicon material 31 and p-type silicon material 32. The metal material 10 is not substantially etched and remains in lines 55 to serve as an access lines 70 (FIGS. 1A, 2).

Dielectric material 15 is then formed within the trenches 57. Additional materials and devices can be formed to complete the array 100, such as the connections to access lines 60 to achieve the structure depicted in FIG. 1A. The cross sectional view of FIG. 1A is taken with respect to line 1A-1A′ shown in FIG. 5A.

FIGS. 6A-6C depict the formation of an individual memory cell 40 according to one embodiment. As shown in FIG. 6A, the conductive material 41 is formed over a substrate 1. The conductive material 41 can be any suitable material. In one embodiment, the conductive material 41 can be a material that, upon oxidation forms any of TiOₓN_{y}, ZrO₂, Al₂O₃ and Ta₂O₅. In one embodiment, the thickness of the conductive material 41 is from about 3 nm to about 80 nm. There can be intervening materials and devices 51 between the conductive material 41 and the substrate 1. The oxide material 42 is formed over the conductive material 41. The oxide material 42 is any of TiOₓN_{y}, ZrO₂, Al₂O₃ and Ta₂O₅. In one embodiment the oxide material 42 is formed by oxidizing a surface of the material 41, as shown in FIG. 6B. For example, where material 41 is TiN, the TiN can be treated with O₂, N₂ and H₂ plasmas. If the oxide material 42 is formed by oxidation of the surface of the conductive material 41, there is a gradient of oxide material 42 to the conductive material 41 which is represented by the broken lines in FIGS. 4A-4C and 6B-6C. In one embodiment, the thickness of the oxide material 42 is from about 2 nm to about 10 nm. The metal material 43, e.g., copper, is formed by any suitable technique in contact with the oxide material 42, as shown in FIG. 6C. In one embodiment, the thickness of the metal material 43 is from about 10 nm to about 100 nm. A desired access device 30 (not shown) can be formed by known methods to be in electrical communication with the memory cell 40.

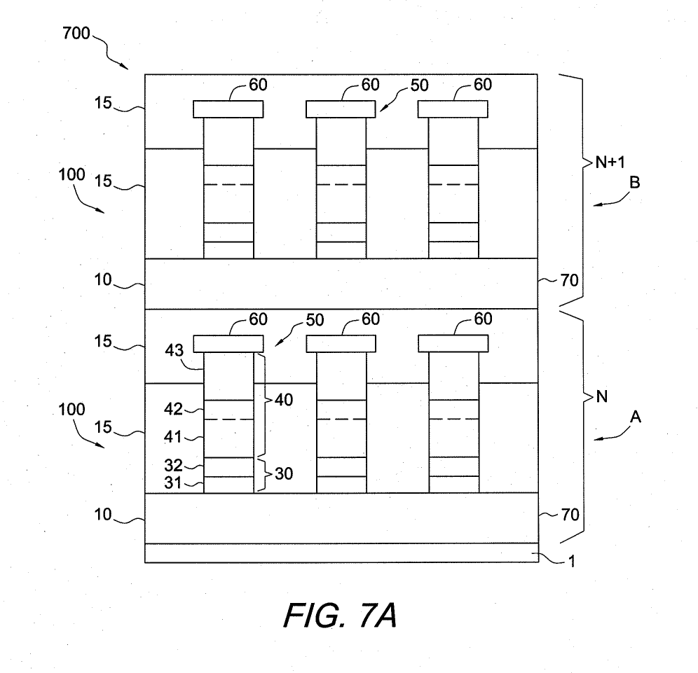

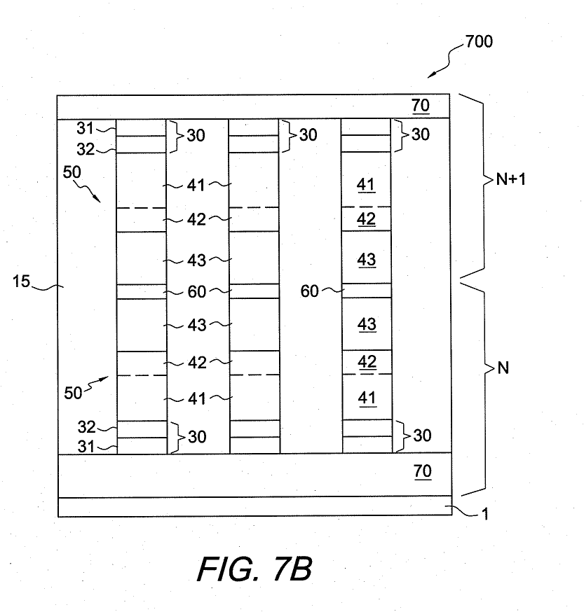

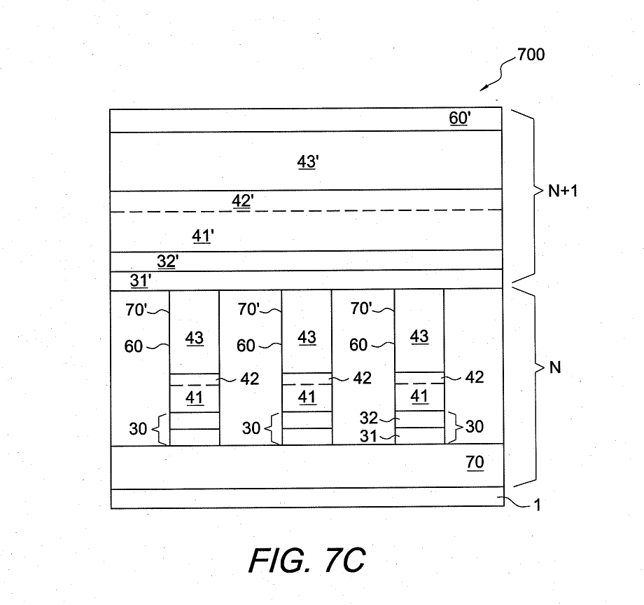

FIG. 7A is a cross-sectional view of a stacked memory array 700 according to an embodiment of the invention. As shown in FIG. 7, multiple planar arrays, such as array 100 (FIG. 1A) can be vertically stacked. While FIG. 7 includes planar arrays 100 having memory cells 40 in accordance with the embodiment of FIG. 3, the stacked array 700 could instead include arrays 101 (FIG. 1B). The memory cells 40 and access devices 30 of level N share a first horizontal plane A and the memory cells 40 and access devices 30 of level N+1 share a second horizontal plane B, stacked above the first horizontal plane A.

The levels N, N+1 can be separated by dielectric material 15 as shown in FIG. 7. As noted above, dielectric material 15 can include one or more different dielectric materials. Alternatively, the dielectric material 15 between the levels N and N+1 can be omitted such that levels N and N+1 share the Cu material 43.

The array 700 is shown having levels N and N+1, but additional levels can be included. Each level N and N+1 of the array 700 can be formed as described above in connection with FIGS. 5A-5E, provided that the dielectric material 15 that separates the levels N and N+1 is formed to have a sufficient thickness to isolate the levels N and N+1 from one another. In one embodiment, the thickness of the dielectric material 15 between a top surface of the copper material 43 of level N and the metal material 10 of level N+1 is from about 10 nm to about 200 nm.

FIG. 7B is a cross-sectional view of a stacked memory array 700 according to another embodiment. The array 700 of FIG. 7B is similar to that shown in FIG. 7A, except that level N+1 has been rotated 180 degrees (from a top to bottom perspective) so that level N and level N+1 share an access line 60. Optionally, the separate access line 60 can be omitted and the metal material 43 can serve as the access line 60 and be shared by levels N and N+1.

FIG. 7C is a cross-sectional view of a stacked memory array 700 according to another embodiment. The array 700 of FIG. 7C is similar to that shown in FIG. 7A, except that level N+1 has been rotated 90 degrees (from a left to right perspective). For clarity, the elements of level N+1 in FIG. 7C are denoted with a “′”. In the FIG. 7C embodiment, the metal material 43 serves as the access line 60 for level N. In addition the metal material 43 serves as the data/sense line 70′ for level N+1.

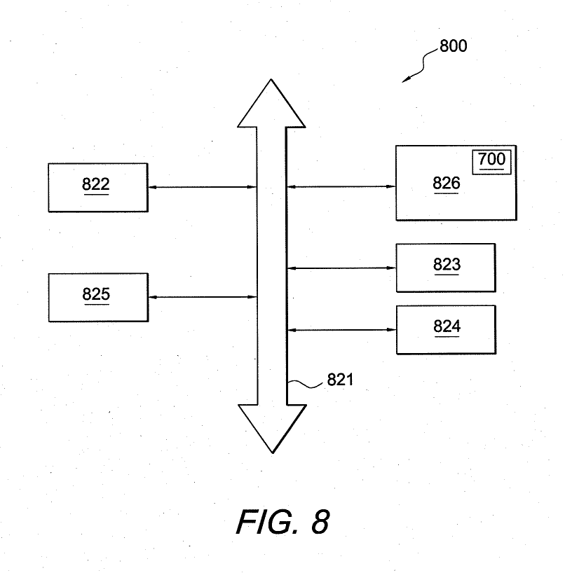

FIG. 8 is a block diagram of a processor system incorporating a memory in accordance with an embodiment of the invention. The FIG. 8 processor system 800, which can be any system including one or more processors, for example, a computer, PDA, phone or other control system, generally comprises a central processing unit (CPU) 822, such as a microprocessor, a digital signal processor, or other programmable digital logic devices, which communicates with an input/output (I/O) device 825 over a bus 821. The memory circuit 826 communicates with the CPU 822 over bus 821 typically through a memory controller. The memory circuit 826 includes the memory array 700 (FIG. 7). Alternatively, the memory circuit can include memory cells and/or arrays according to any embodiment of the invention, including the arrays 100 and 101 depicted in FIGS. 1A and 1B, respectively.

In the case of a computer system, the processor system 800 may include peripheral devices such as a compact disc (CD) ROM drive 823 and hard drive 824, which also communicate with CPU 822 over the bus 821. If desired, the memory circuit 826 may be combined with the processor, for example CPU 822, in a single integrated circuit.

The above description and drawings are only to be considered illustrative of specific embodiments, which achieve the features and advantages described herein. Modification and substitutions to specific process conditions and structures can be made. Accordingly, the embodiments of the invention are not to be considered as being limited by the foregoing description and drawings, but is only limited by the scope of the appended claims.

What is claimed as new and desired to be protected by Letters Patent of the United States is:

1. A memory cell comprising:
an oxide material, the oxide material comprising any one of titanium oxynitride, zirconium oxide, aluminum oxide, and tantalum oxide; and
a metal material in contact with the oxide material.

2. The memory cell of claim 1, wherein the metal material is copper.

3. The memory cell of claim 2, wherein the oxide material is titanium oxynitride and further comprising titanium nitride in contact with the titanium oxynitride.

4. The memory cell of claim 3, wherein the titanium nitride has a thickness from about 3 nm to about 80 nm.

5. The memory cell of claim 3, wherein titanium oxynitride has a thickness from about 2 nm to about 10 nm.

6. The memory cell of claim 3, wherein the copper has a thickness from about 10 nm to about 100 nm.

7. A memory array comprising:
a first plurality of memory cells, each memory cell comprising:
a first conductive material;
a first oxide material in contact with the first conductive material, the first oxide material comprising any one of titanium oxynitride, zirconium oxide, aluminum oxide, and tantalum oxide; and
a first metal material in contact with the first oxide material; and
a first plurality of access devices, each access device electrically connected to a respective memory cell.

8. The memory array of claim 7, wherein each access device is a PN junction diode.

9. The memory array of claim 7, wherein each access device is a transistor.

10. The memory array of claim 7, wherein the first plurality of memory cells and first plurality of access devices are arranged in a plurality of columns and a plurality of rows, and further comprising: a plurality of data/sense lines, each data/sense line electrically connected to each access device within a respective row; and a plurality of access lines, each access line electrically connected to each memory cell within a respective column.

11. The memory array of claim 7, wherein the data/sense lines are bitlines.

12. The memory array of claim 7, wherein the access lines are word lines.

13. The memory array of claim 7, wherein each data/sense line comprises tungsten.

14. The memory array of claim 7, wherein each memory cell is vertically stacked over the respective access device.

15. The memory array of claim 7, wherein each access device is vertically stacked over the respective memory cell.

16. The memory array of claim 7, wherein the memory cells are isolated from one another by a dielectric material.

17. The memory array of claim 16, wherein the dielectric material comprises silicon nitride.

18. The memory array of claim 16, wherein the dielectric material comprises silicon oxide.

19. The memory array of claim 7, further comprising a second plurality of memory cells, wherein the first plurality of memory cells are on a first horizontal plane, the second plurality of memory cells are on a second horizontal plane, and wherein the first horizontal planes is below the second horizontal plane.

20. The memory array of claim 19, wherein each of the second plurality of memory cells comprises:
a second conductive material;
a second oxide material in contact with the second conductive material, the second oxide material comprising any one of titanium oxynitride, zirconium oxide, aluminum oxide, and tantalum oxide; and
a second metal material in contact with the second oxide material; and
further comprising a second plurality of access devices, wherein the first plurality of access devices are on the first horizontal plane, the second plurality of access devices are on the second horizontal plane.

21. The memory array of claim 20, wherein the first and second conductive materials of at least one of the first plurality of memory cells and at least one of the second plurality of memory cells are a same, common conductive material.

22. The memory array of claim 20, wherein the first metal material is above the first conductive material and wherein the second metal material is below the second conductive material.

23. The memory array of claim 19, wherein the first plurality of memory devices and second plurality of memory devices are separated by a dielectric material.

24. The memory array of claim 7, wherein the metal material is copper.

25. The memory array of claim 24, wherein the oxide material is titanium oxynitride and the conductive material is titanium nitride.

26. The memory array of claim 7, wherein each memory cell comprises a vertical stack of the conductive material, oxide material and metal material, and wherein each access device comprises a p-type silicon material in contact with the conductive material.

27. A memory array comprising:
a first plurality of memory cells;
a first plurality of access devices, each of the first plurality of access devices electrically connected to a respective one of the first plurality of memory cells, the first plurality of memory cells and the first plurality of access devices being located on a common first horizontal plane;
a second plurality of memory cells, each of the first and second plurality of memory cells comprising:
titanium nitride;
titanium oxynitride in contact with the titanium nitride; and
copper in contact with the titanium oxynitride; and
a second plurality of access devices, each of the second plurality of access devices a in electrical contact with a respective one of the second plurality of memory cells,
the second plurality of memory cells and the second plurality of access devices located on a common second horizontal plane, the second horizontal plane located over the first horizontal plane.

28. The array of claim 27, wherein each access device comprises a p-type silicon material in contact with the titanium nitride of the respective memory cell and an n-type silicon material in contact with the p-type silicon material.

29. The array of claim 27, wherein the copper is shared between at least one of the first plurality of memory cells and at least one of the second plurality of memory cells.

30. A method of forming a memory array, the method comprising:
forming at least one array level, wherein forming the array level comprises:
forming a stack of materials over a substrate, the stack comprising:
a first metal material;
an n-type silicon material over and in contact with the metal material;
a p-type silicon material over and in contact with the n-type silicon material;
a conductive material over and in contact with the p-type silicon material;
etching the stack to form a plurality of lines of the materials;
forming a first dielectric material over and between the lines;
forming a plurality of first trenches within the dielectric material and perpendicular to the lines, a portion of the bottom surface of each first trench being a top surface of the titanium nitride material;
forming an oxide material on the top surface of the conductive material;
forming a second metal material in the first trenches;
forming a plurality of second trenches, the second trenches formed parallel and adjacent to the first trenches and formed by removing portions of:
the first dielectric material, the n-type silicon material, the p-type silicon material, the conductive material and the oxide material; and
forming a second dielectric material within the second trenches.

31. The method of claim 30, wherein the conductive material is formed having a thickness from about 3 nm to about 80 nm.

32. The method of claim 30, wherein oxide material is formed having a thickness from about 2 nm to about 10 nm.

33. The method of claim 30, wherein the second metal material is formed having a thickness from about 10 nm to about 100 nm.

34. The method of claim 30, wherein the p-type silicon material is formed having a thickness from about 20 nm to about 100 nm.

35. The method of claim 30, wherein the n-type silicon material is formed having a thickness from about 20 nm to about 100 nm.

36. The method of claim 30, further comprising forming first and second array levels, wherein the second array level is directly over at least a portion of the first array level.

37. The method of claim 36, wherein forming the second dielectric material of the first array level comprises forming the second dielectric material over a top surface of the copper material and having a thickness from about 10 nm to about 200 nm over the top surface of the copper material.

38. The method of claim 30, wherein the second metal material comprises copper.

39. The method of claim 38, wherein the oxide material comprises titanium oxynitride.

40. The method of claim 30, wherein the oxide material comprises an oxide selected from the group consisting of titanium oxynitride, zirconium oxide, aluminum oxide, and tantalum oxide.

41. The method of claim 30, wherein the oxide is formed by oxidizing a surface of the conductive material.
